(19) United States
(12) Patent Application Publication
(10) Pub. No.: US 2026/0352095 A1
(43) Pub. Date: Nov. 5, 2026

(54) POWER CONVERSION SYSTEM AND NOISE INFORMATION DETECTION DEVICE

(71) Applicant: Mitsubishi Electric Corporation, Tokyo (JP)

(72) Inventors: Satoshi TAIRA, Tokyo (JP); Masahiro OTSUBO, Tokyo (JP)

(73) Assignee: Mitsubishi Electric Corporation, Tokyo (JP)

(21) Appl. No.: 19/125,308

(22) PCT Filed: Jun. 22, 2023
(86) PCT No.: PCT/JP2023/023172

§ 371 Date: Apr. 29, 2025

(51) Int. Cl. H02M 1/44; G01R 29/26; H02M 7/537

(52) U.S. Cl. CPC H02M 1/44; G01R 29/26; H02M 7/537

(57) ABSTRACT

A power conversion system includes: a power conversion device connected between a power supply and a motor; and a noise information detection device that detects noise information corresponding to a noise current of switching noise generated by the power conversion device. The noise information detection device includes: a damping variable resistor that reduces the noise current; a common mode choke coil through which a main power line and a damping resistor connection line are passed; and a sensor that detects at least one of temperature information and current information of the damping resistor. The power conversion device determines whether a noise level of the noise current is higher than a reference value based on the noise information including at least one of the temperature information and the current information, and lowers a switching carrier frequency in a case where the noise level is higher than the reference value.

### FIELD

The present disclosure relates to a power conversion system that performs power conversion by using a switching element.

### BACKGROUND

In a power conversion device such as an inverter, a converter, or the like, switching is performed at high speed, and therefore switching noise occurs. The switching noise increases in proportion to a switching carrier frequency which is a frequency of a signal that controls switching between on and off of a switching element.

In order to cope with switching noise, in general, a supplier of a power conversion device measures a noise level depending on a switching carrier frequency in advance, and discloses a measurement result. Consequently, in a facility in which the power conversion device is installed, a measure is taken depending on the measurement result. However, in particular, common mode noise propagated via the ground largely depends on a surrounding environment in which the power conversion device is installed, such as the grounding state of a power supply, whether a shielded cable is used, and motor stray capacitance, and therefore a value of an actual noise level and a value of a noise level measured by the supplier may deviate from each other. In addition, it is necessary to use a dedicated measuring instrument in order to measure a noise level of actual switching noise, and thus the noise level cannot be easily measured. As a result, countermeasures are often taken later, for example, countermeasures are considered after occurrence of a problem due to switching noise such as malfunction of a peripheral device, which leads to a large loss in a case where the problem occurs after a facility is in operation. Therefore, it is desired to reduce switching noise in the power conversion device.

An elevator control device described in Patent Literature 1 includes a common mode reactor connected in series to a power conversion device between a power supply and a motor, a magnetic saturation prevention coil wound around a magnetic body of the common mode reactor, and a magnetic saturation prevention resistor provided in proximity to the magnetic saturation prevention coil. The elevator control device determines whether magnetic Saturation of the magnetic body occurs on the basis of an operation pattern of an elevator, and if the elevator control device determines that the magnetic saturation of the magnetic body occurs, the magnetic saturation prevention coil and the magnetic saturation prevention resistor are connected to form a closed circuit to prevent the magnetic saturation, thereby maintaining a noise reduction effect.

### CITATION LIST

### Patent Literature

Patent Literature 1: Japanese Patent Application Laid-open No. 2010-104200

### SUMMARY OF INVENTION

### Problem to be solved by the Invention

However, with the technique of Patent Literature 1 described above, it is necessary to measure a large number of experimental values in advance as a magnetic saturation condition used for determining whether magnetic Saturation occurs for each facility in which the elevator control device is installed, and it takes time and effort to reduce switching noise, which is a problem.

The present disclosure has been made in view of the above, and an object thereof is to provide a power conversion system capable of easily reducing switching noise.

### Means to Solve the Problem

In order to solve the above-described problem and achieve the object, a power conversion system of the present disclosure includes a power conversion device that performs power conversion, the power conversion device being connected between a power supply and a motor, and a noise information detection device that detects noise information that is information corresponding to a noise current of switching noise generated by the power conversion device. The noise information detection device includes a damping resistor that reduces the noise current, and a common mode choke coil through which a main power line connected to the power conversion device is passed and through which an electric wire connected to the damping resistor is passed. The noise information detection device further includes a sensor that detects at least one of temperature information that is information on a temperature of the damping resistor and current information that is information on a current flowing through the damping resistor, the temperature information and the current information changing depending on a change in the noise current. The power conversion device receives the noise information including at least one of the temperature information and the current information from the noise information detection device, determines whether a noise level of the noise current is higher than a reference value on the basis of the noise information, and lowers a switching carrier frequency in a case where the noise level is higher than the reference value.

### Effects of the Invention

The power conversion system according to the present disclosure achieves an effect that it is possible to easily reduce switching noise.

### BRIEF DESCRIPTION OF DRAWINGS

FIG. 1 is a diagram illustrating a first exemplary configuration of a power conversion system according to an embodiment.

FIG. 2 is a diagram illustrating a second exemplary configuration of a power conversion system according to the embodiment.

FIG. 3 is a flowchart illustrating a processing procedure of a process executed by the power conversion system according to the embodiment.

FIG. 4 is a diagram for explaining a process in a case where the power conversion system according to the embodiment lowers a switching carrier frequency before noise information reaches a noise determination value.

FIG. 5 is a diagram illustrating an exemplary hardware configuration that realizes a control unit according to the embodiment.

### DESCRIPTION OF EMBODIMENTS

Hereinafter, a power conversion system according to an embodiment of the present disclosure will be described in detail with reference to the drawings.

### Embodiment

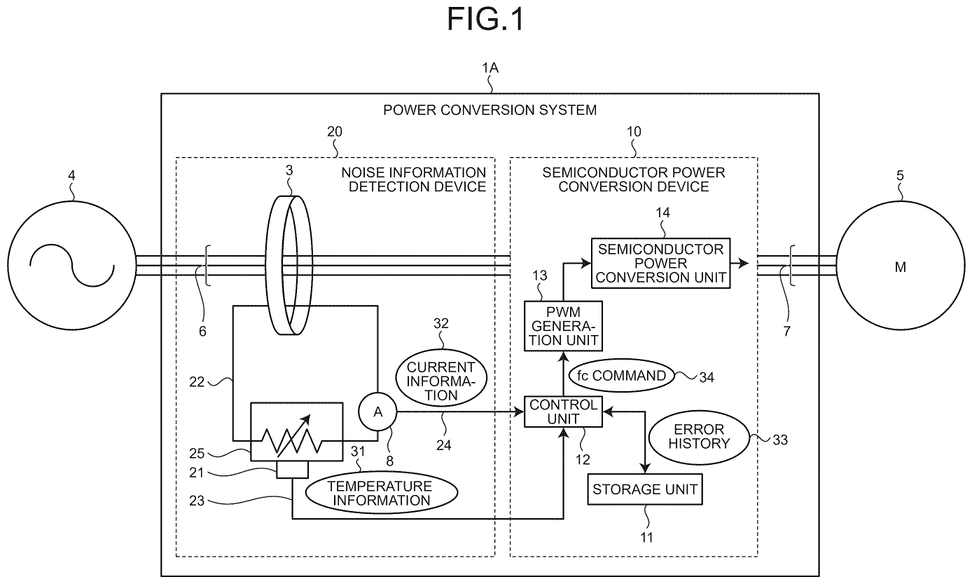

FIG. 1 is a diagram illustrating a first exemplary configuration of a power conversion system according to an embodiment. A power conversion system JA is a system that performs power conversion by using a switching element.

The power conversion system 1A drives a motor 5 by using power from a power supply 4, automatically detects switching noise, and automatically reduces the switching noise. The power conversion system 1A includes a semiconductor power conversion device 10, a noise information detection device 20, an input power line 6 which is a three-phase collective main power line, and an output power line 7 which is a three-phase collective main power line.

The power conversion system 1A is connected to the power supply 4 and the motor 5. The power conversion system IA is a system in which a damping variable resistor 25 is mounted on a power supply 4 side (primary side).

That is, in the power conversion system 1A, the noise information detection device 20 including the damping variable resistor 25 is connected between the power supply 4 and the semiconductor power conversion device 10 which is a power conversion device including a pulse width modulation (PWM) converter (not illustrated).

The semiconductor power conversion device 10 is a device that is connected between the power supply 4 and the motor 5 and performs power conversion. The semiconductor power conversion device 10 is connected to the power supply 4 through the input power line 6, and is connected to the motor 5 through the output power line 7.

The noise information detection device 20 detects noise information which is information corresponding to switching noise generated by the semiconductor power conversion device 10. The noise information detection device 20 includes a common mode choke coil 3, the damping variable resistor 25, a temperature sensor 21, a current sensor 8, a damping resistor connection line 22, a temperature sensor connection line 23, and a current sensor connection line 24. The damping resistor connection line 22, the temperature sensor connection line 23, and the current sensor connection line 24 are electric wires. The noise information detection device 20 of the embodiment detects the noise information by using the damping variable resistor 25.

The common mode choke coil 3 is disposed at the input power line 6. The input power line 6 and the damping resistor connection line 22 connected to the damping variable resistor 25 are passed through the central portion of the cylindrical portion of the common mode choke coil 3.

The damping variable resistor 25 is a resistor that attenuates vibration to reduce a noise current of switching noise, and is connected to the damping resistor connection line 22. The damping resistor connection line 22 extends from one end of the damping variable resistor 25, passes through the interior of the annulus of the common mode choke coil 3 in an annular shape, and is connected to another end of the damping variable resistor 25. The current sensor 8 is connected on the damping resistor connection line 22.

The damping variable resistor 25 is a resistor capable of changing a resistance value. That is, the resistance value of the damping variable resistor 25 is variable by a user of the power conversion system 1A. Therefore, the power conversion system 1A can easily adjust the degree of noise reduction.

The current sensor 8 measures a current flowing through the damping resistor connection line 22 (hereinafter, the current may be referred to as a damping circuit current). The current sensor 8 is connected to the semiconductor power conversion device 10 through the current sensor connection line 24. The current sensor 8 transmits current information 32 indicating a measurement result of the current flowing through the damping resistor connection line 22 to the semiconductor power conversion device 10 through the current sensor connection line 24.

The temperature sensor 21 is disposed at the damping variable resistor 25. The temperature sensor 21 measures a temperature of the damping variable resistor 25 (hereinafter, the temperature may be referred to as a damping resistance temperature). The temperature sensor 21 is connected to the semiconductor power conversion device 10 through the temperature sensor connection line 23. The temperature sensor 21 transmits temperature information 31 indicating a measurement result of the temperature of the damping variable resistor 25 to the semiconductor power conversion device 10 through the temperature sensor connection line 23.

The semiconductor power conversion device 10 includes a storage unit 11, a control unit 12, a PWM generation unit 13, and a semiconductor power conversion unit 14. The storage unit 11, the control unit 12, the PWM generation unit 13, and the semiconductor power conversion unit 14 are configured by using semiconductor elements.

The storage unit 11 stores an error history 33 indicating a history of errors that have occurred in the power conversion system 1A. The error history 33 includes the presence or absence of error occurrence, information on a history of the damping resistor temperature when an error occurs, and the damping circuit current. The error history 33 may further include information such as a rate of increase in the damping resistor temperature and a rate of increase in the damping circuit current when an error occurs, and the number of errors that have occurred.

The control unit 12 receives the temperature information 31 from the temperature sensor 21 of the noise information detection device 20. In addition, the control unit 12 receives the current information 32 from the current sensor 8 of the noise information detection device 20. Information including at least one of the temperature information 31 and the current information 32 is noise information. The control unit 12 reads the error history 33 from the storage unit 11.

The control unit 12 generates a frequency command (hereinafter, referred to as an fc command 34) which is a command designating a switching carrier frequency on the basis of at least one of the temperature information 31 and the current information 32. The switching carrier frequency is a frequency of a signal that controls switching between on and off of a switching element. The control unit 12 may generate the fc command 34 with reference to the error history 33.

In a case where the damping resistor temperature indicated by the temperature information 31 is higher than a temperature threshold, the control unit 12 generates the fc command 34 that indicates a switching carrier frequency lower than a current switching carrier frequency. In addition, in a case where the damping circuit current indicated by the current information 32 is higher than a current threshold, the control unit 12 generates the fc command 34 that indicates a switching carrier frequency lower than the current switching carrier frequency.

Furthermore, the control unit 12 predicts whether an error occurs thereafter on the basis of the error history 33, and at least one of the temperature information 31 and the current information 32. If the control unit 12 determines that an error occurs thereafter, the control unit 12 generates the fc command 34 that indicates a switching carrier frequency lower than the current switching carrier frequency. The control unit 12 transmits the generated fc command 34 to the PWM generation unit 13.

The PWM generation unit 13 generates a PWM signal on the basis of the fc command 34. The PWM signal is, for example, a signal for controlling a PWM converter (not illustrated) included in the semiconductor power conversion unit 14. The PWM generation unit 13 transmits the PWM signal to the semiconductor power conversion unit 14.

The semiconductor power conversion unit 14 includes the PWM converter and an inverter (not illustrated), and converts power sent from the power supply 4. In the semiconductor power conversion unit 14, the PWM converter converts alternating-current power sent from the power supply 4 into direct-current power on the basis of the PWM signal. In addition, in the semiconductor power conversion unit 14, the inverter converts direct-current power into alternating current power to drive the motor 5.

As described above, in the power conversion system 1A in which the damping variable resistor 25 is connected to the PWM converter and the power supply 4, the power supply 4 and the semiconductor power conversion device 10 are connected through the input power line 6, and the semiconductor power conversion device 10 and the motor 5 are connected through the output power line 7. The common mode choke coil 3 is disposed at the input power line 6, the damping resistor connection line 22 is connected contactlessly to the common mode choke coil 3, and the damping variable resistor 25 is connected to the damping resistor connection line 22. In addition, the temperature sensor 21 is disposed in the vicinity of the damping variable resistor 25, and the temperature sensor 21 is connected to the semiconductor power conversion device 10 through the temperature sensor connection line 23.

In the power conversion system 1A, a resistor connected to the damping resistor connection line 22 that passes through the common mode choke coil 3 is the damping variable resistor 25, and a resistance value is variable.

Consequently, for the power conversion system 1A, the resistance value can be selected regardless of the amount of noise in the power conversion system 1A, and the power can be consumed by the damping variable resistor 25, which makes it easy to select the current sensor 8 connected in series to the damping variable resistor 25. In addition, in the power conversion system 1A, in a case where it is desired to change the resistance value depending on the capacity of the inverter, the size of the facility in which the power conversion system 1A is installed, and the like, the resistance value can be easily changed by using the damping variable resistor 25.

As described above, the damping resistor connection line 22 connected to the damping variable resistor 25 is passed through the common mode choke coil 3 together with the input power line 6 which is a three-phase collective main power line. In the power conversion system 1A, when a noise current flows through the input power line 6, a current proportional to the noise current also flows through the damping variable resistor 25 by an induced electromotive force of the common mode choke coil 3, the noise current is consumed by the damping variable resistor 25, and the temperature of the damping variable resistor 25 increases.

The damping variable resistor 25 generates heat in proportion to the noise current flowing through the damping variable resistor 25. That is, the noise current flowing through the damping variable resistor 25 and the amount of heat generated in the damping variable resistor 25 are in a proportional relationship. Therefore, the control unit 12 can determine the noise level of the noise current on the basis of the temperature of the damping variable resistor 25 (damping resistor temperature) corresponding to the amount of heat generated in the damping variable resistor 25. The control unit 12 of the embodiment determines that the noise level is higher than a reference value in a case where the temperature of the damping variable resistor 25 measured by the temperature Sensor 21 exceeds the temperature threshold.

In addition, since a current proportional to the noise current flows through the damping variable resistor 25, the control unit 12 can determine the noise level of the noise current on the basis of the current flowing through the damping variable resistor 25 (damping circuit current) measured by the current sensor 8. The control unit 12 of the embodiment may determine that the noise level is higher than the reference value when the current measured by the current sensor 8 exceeds the current threshold.

When the control unit 12 determines that the noise level is higher than the reference value, the semiconductor power conversion device 10 performs switching so as to lower the switching carrier frequency in order to lower the noise level. Specifically, when determining that the noise level is higher than the reference value, the control unit 12 generates the fc command 34 that indicates a switching carrier frequency lower than the current switching carrier frequency.

For example, the control unit 12 generates the fc command 34 that indicates a switching carrier frequency lower than the current switching carrier frequency by a specific value. In addition, the control unit 12 may generate, for example, the fc command 34 that indicates a switching carrier frequency lower than the current switching carrier frequency by a specific rate. The control unit 12 transmits the generated fc command 34 to the PWM generation unit 13.

Consequently, the PWM generation unit 13 generates a PWM signal corresponding to the fc command 34 and transmits the PWM signal to the semiconductor power conversion unit 14. In the semiconductor power conversion unit 14, the PWM converter converts alternating-current power sent from the power supply 4 into direct-current power on the basis of the PWM signal, and the inverter converts direct-current power into alternating-current power to drive the motor 5.

As described above, when the power conversion system 1A determines that the noise level is higher than the reference value on the basis of at least one of the temperature measured by the temperature sensor 21 and the current measured by the current sensor 8, the power conversion system 1A lowers the switching carrier frequency, so that the switching noise can be easily reduced.

In addition, in the power conversion system 1A, since the noise current can be consumed by the damping variable resistor 25, switching noise can be reduced, and efficient system operation can be performed.

The power conversion system 1A may determine whether the noise level is higher than the reference value on the basis of both a feedback value from the temperature sensor 21 and a feedback value from the current sensor 8.

That is, the control unit 12 may determine whether the noise level is higher than the reference value on the basis of both the temperature measured by the temperature sensor 21 and the current measured by the current sensor 8.

Consequently, the control unit 12 can accurately determine whether the noise level is higher than the reference value.

For example, in a case where the damping resistor temperature which is the temperature measured by the temperature sensor 21 is higher than the temperature threshold and the damping circuit current which is the current measured by the current sensor 8 is higher than the current threshold, the control unit 12 determines that the noise level is higher than the reference value.

In addition, the control unit 12 may determine that the noise level is higher than the reference value in a case where the damping resistor temperature is higher than the temperature threshold or the damping circuit current is higher than the current threshold.

Note that, in the embodiment, the configuration has been described in which the noise information detection device 20 includes both the temperature sensor 21 and the current sensor 8, but the power conversion system 1A only needs to include at least one of the temperature sensor 21 and the current sensor 8 since it is sufficient that the noise level can be detected by using the damping variable resistor 25.

As described above, the control unit 12 determines whether the noise level is higher than the reference value on the basis of at least one of the temperature measured by the temperature sensor 21 and the current measured by the current sensor 8.

As described above, while reducing the common mode noise by the damping variable resistor 25, the power conversion system 1A lowers the switching carrier frequency in a case where the noise level detected by using the damping variable resistor 25 is high, so that the noise level can be automatically lowered.

Note that the damping variable resistor 25 may be mounted on a motor 5 side (secondary side). Here, a configuration of a power conversion system in a case where the damping variable resistor 25 is connected to the motor 5 side will be described.

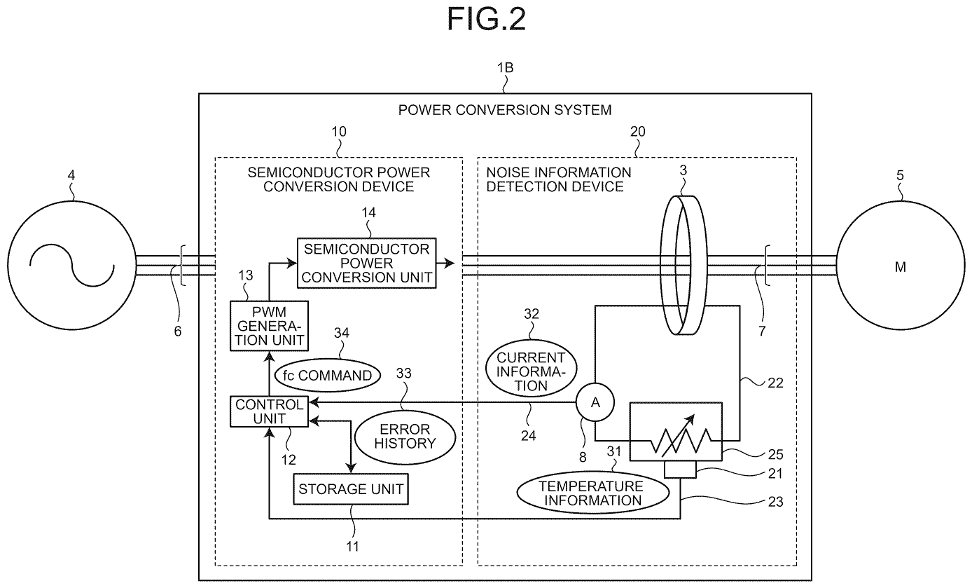

FIG. 2 is a diagram illustrating a second exemplary configuration of a power conversion system according to the embodiment. Regarding components among components in FIG. 2 that achieve the same functions as those of the power conversion system 1A illustrated in FIG. 1, the same reference signs are assigned thereto, and repetitive descriptions thereof will be omitted.

Similarly to the power conversion system 1A, a power conversion system 1B is a system that drives the motor 5 by using power from the power supply 4, automatically detects noise, and automatically reduces the noise. Similarly to the power conversion system 1A, the power conversion system 1B includes the semiconductor power conversion device 10, the noise information detection device 20, the input power line 6, and the output power line 7.

The power conversion system 1B is connected to the power supply 4 and the motor 5. In the power conversion system 1B, the noise information detection device 20 including the damping variable resistor 25 is connected between the motor 5 and the semiconductor power conversion device 10 including the PWM converter.

In the power conversion system 1B, the common mode choke coil 3 is disposed at the output power line 7. The output power line 7 and the damping resistor connection line 22 are passed through the central portion of the cylindrical portion of the common mode choke coil 3

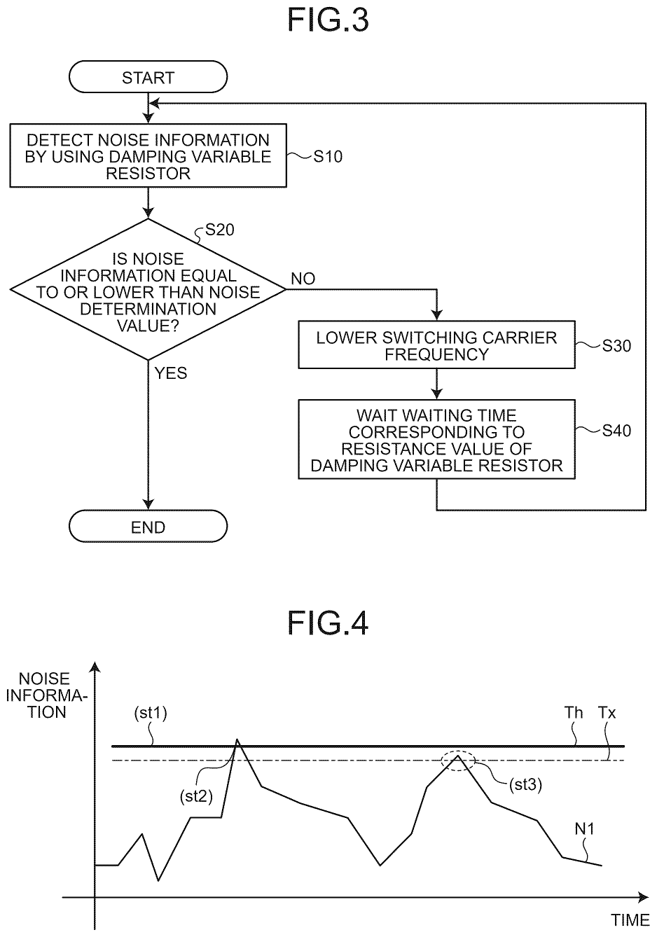

Next, a processing procedure of a process executed by each of the power conversion systems 1A and 1B will be described. FIG. 3 is a flowchart illustrating the processing procedure of the process executed by the power conversion system according to the embodiment. Since the processing procedures of the processes executed by the power conversion systems 1A and 1B are the same, the processing procedure of the process executed by the power conversion system 1A will be described here.

A noise determination value (a noise determination value Th to be described later) which is a threshold used for determination of noise information is set on the power conversion system 1A by the user of the power conversion system 1A. That is, at least one of the temperature threshold and the current threshold is set on the power conversion system 1A by the user of the power conversion system 1A.

When the power conversion system 1A starts driving the motor 5, the noise information detection device 20 detects the noise information by using the damping variable resistor 25 (step S10). Specifically, in a case where the power conversion system 1A includes the temperature sensor 21, the temperature sensor 21 detects the damping resistor temperature. In addition, in a case where the power conversion system 1A includes the current sensor 8, the current sensor 8 detects the damping circuit current.

The noise information detection device 20 transmits the noise information to the control unit 12 of the semiconductor power conversion device 10. The control unit 12 determines whether the noise information is equal to or lower than the noise determination value Th (step S20). Specifically, in the case where the power conversion system 1A includes the temperature sensor 21, the control unit 12 determines whether the damping resistor temperature measured by the temperature sensor 21 is equal to or lower than the temperature threshold. In addition, in the case where the power conversion system 1A includes the current sensor 8, the control unit 12 determines whether the damping circuit current measured by the current sensor 8 is equal to or lower than the current threshold.

If the noise information is higher than the noise determination value Th (step S20, No), the control unit 12 determines that the noise level is higher than the reference value. That is, if the damping resistor temperature is higher than the temperature threshold, the control unit 12 determines that the noise level is higher than the reference value. If the damping circuit current is higher than the current threshold, the control unit 12 determines that the noise level is higher than the reference value. When determining that the noise level is higher than the reference value, the control unit 12 lowers the switching carrier frequency (step S30).

Thereafter, the noise information detection device 20 waits a waiting time corresponding to the resistance value of the damping variable resistor 25 (step S40), and returns to the process of step S10. Then, the noise information detection device 20 detects the noise information by using the damping variable resistor 25 (step S10). The control unit 12 determines whether the noise information is equal to or lower than the noise determination value Th (step S20). If the noise information is equal to or lower than the noise determination value Th (step S20, Yes), the control unit 12 determines that the noise level is equal to or lower than the reference value and does not change the switching carrier frequency.

Note that the semiconductor power conversion device 10 may lower the switching carrier frequency before the noise information reaches the noise determination value Th. Here, a process in a case where the semiconductor power conversion device 10 lowers the switching carrier frequency before the noise information reaches the noise determination value Th will be described.

FIG. 4 is a diagram for explaining the process in the case where the power conversion system according to the embodiment lowers the switching carrier frequency before the noise information reaches the noise determination value. FIG. 4 illustrates an example of transition of noise information N1 in a case where the semiconductor power conversion device 10 adjusts the switching carrier frequency.

The semiconductor power conversion device 10 sets the noise determination value Th which is a threshold of the noise information N1 in advance in accordance with an instruction from the user (st1). The threshold of the noise information N1 includes at least one of the temperature threshold and the current threshold.

When the power conversion system 1A starts driving the motor 5, the noise information detection device 20 detects the noise information N1 by using the damping variable resistor 25. When the noise information N1 exceeds the noise determination value Th, the semiconductor power conversion device 10 determines that an error has occurred (st2) and lowers the switching carrier frequency. Consequently, the noise information NI detected by the noise information detection device 20 decreases.

The storage unit 11 of the semiconductor power conversion device 10 stores the error history 33 indicating a history of errors that have occurred in the power conversion system 1A. Here, the storage unit 11 stores, as the error history 33, a fact that the noise information N1 exceeds the noise determination value Th. When the error history 33 is stored in the storage unit 11, the control unit 12 of the semiconductor power conversion device 10 reads the error history 33 from the storage unit 11. When reading the error history 33, the control unit 12 generates the fc command 34 on the basis of the error history 33.

For example, even once the noise information N1 exceeds the noise determination value Th, the control unit 12 generates the fc command 34 so that the noise information NI does not exceed the noise determination value Th thereafter. Specifically, the control unit 12 sets a new noise determination value Tx lower than the noise determination value Th by a specific value or a new noise determination value Tx lower than the noise determination value Th by a specific rate on the basis of the noise determination value Th. Then, after setting the new noise determination value Tx, the control unit 12 lowers the switching carrier frequency when the noise information N1 exceeds the new noise determination value Tx. Consequently, the control unit 12 can lower the switching carrier frequency before the noise information N1 exceeds the initial noise determination value Th (st3).

There is a method for measuring a magnetic flux flowing through an iron core of the common mode choke coil 3 and lowering the switching carrier frequency when the magnetic flux exceeds a protection level. In a case of this method, it is necessary to measure the magnetic flux flowing through the iron core, which results in a complicated and expensive facility.

On the other hand, since the power conversion systems 1A and 1B according to the embodiment lower the switching carrier frequency in a case where the noise information NI exceeds the noise determination value Th, it is possible to reduce the switching noise without measuring the magnetic flux flowing through the iron core.

As described above, since the power conversion systems 1A and 1B do not measure the magnetic flux, the switching noise can be reduced with an inexpensive system configuration. In addition, since the power conversion systems 1A and 1B consume the noise current by the damping variable resistor 25, the switching noise can be reduced.

Note that instead of the damping variable resistor 25, a damping resistor that cannot change the resistance value may be applied to the power conversion systems 1A and 1B.

In addition, since the power conversion systems 1A and 1B can automatically lower the switching carrier frequency depending on the noise level, it is possible to prevent shut-down of the power conversion systems 1A and 1B and to reduce the switching noise.

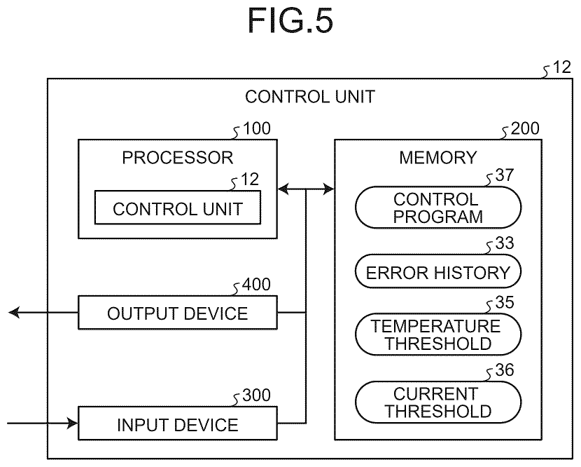

Here, a hardware configuration of the control unit 12 will be described. FIG. 5 is a diagram illustrating an exemplary hardware configuration that realizes the control unit according to the embodiment. The control unit 12 can be realized by an input device 300, a processor 100, a memory 200, and an output device 400. Examples of the processor 100 include a central processing unit (CPU, also referred to as a processing device, an arithmetic device, a microprocessor, a microcomputer, or a digital signal processor (DSP) ), and system large scale integration (LSI). Examples of the memory 200 include a random access memory (RAM) and a read only memory (ROM).

The control unit 12 is realized by the processor 100 reading and executing a computer-executable control program 37 stored in the memory 200 for performing an operation of the control unit 12. It can also be said that the control program 37 which is a program for performing an operation of the control unit 12 causes a computer to execute a procedure or a method of the control unit 12.

The control program 37 executed by the processor 100 has a modular configuration including the control unit 12, and these components are loaded on a main storage device and generated on the main storage device.

The input device 300 receives the damping resistor temperature from the temperature sensor 21 and sends the damping resistor temperature to the processor 100. In addition, the input device 300 receives the damping circuit current from the current sensor 8 and sends the damping circuit current to the processor 100.

The memory 200 stores the control program 37, the error history 33, a temperature threshold 35, a current threshold 36, and the like. In addition, the memory 200 is used as a temporary memory when the processor 100 executes various processes. The output device 400 outputs a drive current of the motor 5 to the motor 5.

The control program 37 may be stored in a computer-readable storage medium as a file in an installable format or an executable format and provided as a computer program product. The control program 37 may also be provided to the control unit 12 via a network such as the Internet. A part of the functions of the control unit 12 may be realized by dedicated hardware such as a dedicated circuit and another part thereof may be realized by software or firmware. Note that a hardware configuration of a part of the functions of the control unit 12 may be the hardware configuration illustrated in FIG. 5.

As described above, according to the embodiment, the power conversion systems 1A and 1B determine whether the noise level of the noise current is higher than the reference value on the basis of the noise information N1 detected by using the damping variable resistor 25, and lower the switching carrier frequency in a case where the noise level is higher than the reference value, so that the switching noise can be easily reduced. In addition, since the power conversion systems 1A and 1B can consume the noise current by the damping variable resistor 25, the switching noise can be reduced.

The configurations described in the embodiment above are merely examples and can be combined with other known technology and part of the configurations can be omitted or modified without departing from the gist thereof.

### REFERENCE SIGNS LIST

1A, 1B power conversion system; 3 common mode choke coil; 4 power supply; 5 motor; 6 input power line; 7 output power line; 8 current sensor; 10 semiconductor power conversion device; 11 storage unit; 12 control unit; 13 PWM generation unit; 14 semiconductor power conversion unit; 20 noise information detection device; 21 temperature sensor; 22 damping resistor connection line; 23 temperature sensor connection line; 24 current sensor connection line; 25 damping variable resistor; 31 temperature information; 32 current information; 33 error history; 34 fc command; 35 temperature threshold; 36 current threshold; 37 control program; 100 processor ; 200 memory; 300 input device; 400 output device; N1 noise information; Th noise determination value; Tx new noise determination value.

1. A power conversion system comprising:
a power converter to perform power conversion, the power converter being connected between a power supply and a motor; and
a noise information detector to detect noise information that is information corresponding to a noise current of switching noise generated by the power converter, wherein
the noise information detector includes:
a damping resistor to reduce the noise current;
a common mode choke coil through which a main power line connected to the power converter is passed and through which an electric wire connected to the damping resistor is passed; and
a sensor to detect at least one of temperature information that is information on a temperature of the damping resistor and current information that is information on a current flowing through the damping resistor, the temperature information and the current information changing depending on a change in the noise current, and
the power converter
receives the noise information including at least one of the temperature information and the current information from the noise information detector, determines whether a noise level of the noise current is higher than a reference value on a basis of the noise information, and lowers a switching carrier frequency in a case where the noise level is higher than the reference value.

2. The power conversion system according to claim 1, wherein
the noise information detector is connected to a side of the power supply that is a primary side of the power converter.

3. The power conversion system according to claim 1, wherein
the noise information detector is connected to a side of the motor that is a secondary side of the power converter.

4. The power conversion system according to claim 1, wherein
the damping resistor is a damping variable resistor in which a resistance value is variable.

5. The power conversion system according to claim 1, wherein
the power converter
sets, after the noise level exceeds a noise determination value that is the reference value, a new noise determination value lower than the noise determination value, and lowers the switching carrier frequency when the noise level becomes higher than the new noise determination value.

6. The power conversion system according to claim 2, wherein
the power converter
sets, after the noise level exceeds a noise determination value that is the reference value, a new noise determination value lower than the noise determination value, and lowers the switching carrier frequency when the noise level becomes higher than the new noise determination value.

7. The power conversion system according to claim 3, wherein
the power converter
sets, after the noise level exceeds a noise determination value that is the reference value, a new noise determination value lower than the noise determination value, and lowers the switching carrier frequency when the noise level becomes higher than the new noise determination value.

8. The power conversion system according to claim 4, wherein
the power converter
sets, after the noise level exceeds a noise determination value that is the reference value, a new noise determination value lower than the noise determination value, and lowers the switching carrier frequency when the noise level becomes higher than the new noise determination value.

9. A noise information detector to detect noise information that is information corresponding to a noise current of switching noise generated by a power converter connected between a power supply and a motor for performing power conversion, the noise information detector comprising:
a damping resistor to reduce the noise current;
a common mode choke coil through which a main power line connected to the power converter is passed and through which an electric wire connected to the damping resistor is passed; and
a sensor to detect at least one of temperature information that is information on a temperature of the damping resistor and current information that is information on a current flowing through the damping resistor, the temperature information and the current information changing depending on a change in the noise current.
